(19) United States
(12) Patent Application Publication
(10) Pub. No.: US 2009/0243597 A1
(43) Pub. Date: Oct. 1, 2009

(54) Methods and Apparatus for Security Device Portal Sensing

(75) Inventors: John Spenik, Phoenix, AZ (US); Brian Woodbury, Gilbert, AZ (US); Roc Lastinger, Cave Creek, AZ (US)

Correspondence Address: LETHAM LAW FIRM, LLC, 914 N. TUCANA LANE, GILBERT, AZ, 85234, US

(73) Assignee: Quixcode LLC, Scottsdale, AZ (US)

(21) Appl. No.: 12/414,356

(22) Filed: Mar. 30, 2009

Related U.S. Application Data
(60) Provisional application No. 61/041,526, filed on Apr. 1, 2008.

(51) Int. Cl. G01B 7/14; G01R 33/00

(52) U.S. Cl. 324/207.22; 324/260

(57) ABSTRACT

A security device, according to various aspects of the present invention, secures an area accessible through a portal (e.g., doorway, window opening, hatch, vent) against unreported ingress or egress (e.g., access). A security device monitors a portal or a portal cover (e.g., door, window, screen, flap) to provide reports of access; a warning of unauthorized access; authentication of authorized users; and status of the security device.

### CROSS-REFERENCE TO RELATED APPLICATIONS

This application claims benefit under 35 U.S.C. §119(e) of U.S. Provisional Application No. 61/041,526 filed Apr. 1, 2008 herein incorporated by reference.

### FIELD OF THE INVENTION

Embodiments of the present invention relate to apparatus for monitoring access to an area through a portal.

### BACKGROUND OF THE INVENTION

Conventional security devices have been used to control access to a secured area. Access control includes detecting unauthorized ingress and/or egress. A security device that controls access to an area through a portal may benefit from a configuration that spans a joint (e.g., separation) between two portal covers or between a portal cover and frame of the portal.

### SUMMARY OF THE INVENTION

A system that detects movement of a portal cover. The system includes a main unit, a remote unit, and a coupler. The main unit includes a sensor for detecting a magnetic field. The remote unit includes a magnet that provides the magnetic field. The coupler communicates the magnetic field to the sensor. The main unit couples to a first object that includes a portal structure or a portal cover. The remote unit couples to a second object that includes a portal structure or a portal cover. The first object or the second object moves with respect to the other object at a boundary between the first object and the second object. While the coupler magnetically couples to the main unit and the remote unit across the boundary, the sensor detects the magnetic field via the coupler. A movement greater than a threshold of the first object or the second object magnetically decouples the coupler from the main unit or the remote unit whereby the sensor does not detect the magnetic field.

A system that detects movement of a portal cover. The system includes a main unit, a remote unit, and a coupler. The remote unit includes a magnet that provides a magnetic field and a sensor for detecting the magnetic field. The coupler electrically couples the main unit to the remote unit. The main unit couples to a first object that includes a portal structure or a portal cover. The remote unit couples to a second object that includes a portal structure or a portal cover. The first object or the second object moves with respect to the other object at a boundary between the first object and the second object. While the sensor is positioned proximate to the magnet, the sensor detects the magnetic field and provides an electrical signal in accordance with detecting. While the coupler electrically couples the main unit to the remote unit across the boundary, the main unit receives the electrical signal via the coupler. A movement greater than a threshold of the first object or the second object decouples the coupler from the main unit or the remote unit whereby the main unit does not receive the electrical signal.

A system that detects movement of a portal cover. The system includes a main unit and an arm. The main unit includes a sensor for detecting a magnetic field. The arm includes a magnet. The arm is pivotally coupled to the main unit. The arm moves between a secured position and an unsecured position. The main unit couples to a first object that includes a portal structure or a portal cover. While in the secured position, the arm extends from the first object across a boundary to a second object that includes a portal structure or a portal cover and positions the magnet proximate to the sensor whereby the sensor detects the magnetic field. While in the unsecured position, the arm does not extend across the boundary to a second object and the magnet is positioned away from the sensor whereby the sensor detects a reduced magnitude of the magnetic field. The first object or the second object moves with respect to the other object at a boundary between the first object and the second object. A movement greater than a threshold of the first object or the second object moves the arm from the secure position to the unsecured position.

### BRIEF DESCRIPTION OF THE DRAWING

Embodiments of the present invention will now be further described with reference to the drawing, wherein like designations denote like elements, and:

FIG. 1 is a functional block diagram of an system having a coupler that communicates a magnetic field according to various aspects of the present invention;

FIG. 2 is a functional block diagram of an system having a coupler that communicates an electrical signal according to various aspects of the present invention;

FIG. 3 is a functional block diagram of an system having an arm according to various aspects of the present invention;

FIGS. 4 and 5 are plan views of the system of FIG. 2;

FIGS. 6 and 7 are plan views of the system of FIG. 1; and

FIGS. 8, 9, and 10 are plan views of the system of FIG. 3.

### DETAILED DESCRIPTION OF THE PREFERRED EMBODIMENTS

A security device, according to various aspects of the present invention, secures an area accessible through a portal (e.g., doorway, window opening, hatch, vent) against unreported ingress or egress (e.g., access). A security device monitors a portal or a portal cover (e.g., door, window, screen, flap) to provide reports of access; a warning of unauthorized access; authentication of authorized users; and status of the security device.

A security device may couple to a portal cover. A security device may couple to a portal structure (e.g., frame, header, wall proximate to portal, lintel, second door of a double door, jam, sill, doorstop, casing, brickmold, frame). A security device may include a structure (e.g., coupler, arm, conductor) that spans a portal, a portal cover, or between a portion of a portal structure and a portion of a portal cover to detect access. A security device may include a first portion that couples to a first object (e.g., a portal cover or a portal structure), a second portion that couples to a second object (e.g., a portal cover or a portal structure), and a structure that couples the first portion to the second portion across an area (e.g., boundary) where the first object and the second object met and move with respect to each other.

A structure that spans a portal, a portal cover, or a boundary between a portal and a portal cover may detect movement of a portal cover. Movement of a portal cover greater than a threshold provides evidence of access. A structure that spans a portal, a portal cover, or a boundary between a portal and a portal cover may further provide a physical stimulus (e.g., electrical, magnetic, pressure, movement, temperature, light, electromagnetic radiation). A physical stimulus may be responsive to movement of a portal cover. Presence or absence of a physical stimulus via the structure may provide evidence of access. For example, a structure that spans may provide a physical stimulus while positioned across a portal or a portal cover. Movement of the structure away from it present position or removal of the structure from the portal or portal cover interrupts provision of the physical stimulus thereby providing evidence of access.

A security device may detect changes (e.g., increase, decrease, average value, rate of change, departure from a quiescent value) in physical stimulus as indicia of access to an area. A security device may detect physical quantities of heat, light, vibration, and magnetic flux.

The security device described herein may be of the type described in U.S. patent application Ser. No. 11/955,665 filed Dec. 13, 2007, U.S. patent application Ser. No. 11/955,682 filed Dec. 13, 2007, or U.S. patent application Ser. No. 11/955,703 filed Dec. 13, 2007. Each of the forgoing U.S. patent applications is herein incorporated by reference.

A security device may include one or more sensors that monitors the status (e.g., open, closed, partially open) of a portal cover or the status (e.g., present, absent, providing stimulus, not providing stimulus, closed position, open position) of a structure that spans a portal or portal cover.

A security device detects ingress and egress through a portal to and from an area. A security device detects physical stimulus, physical quantities, physical characteristics, or a change in a physical quantity or characteristic. A security device may detect movement of a portal cover as an indication of access through a portal. A security device may report an event. Events may include greater than threshold amount of movement (e.g., opening, closing) of a portal cover, greater than threshold duration of a portal cover in a particular position (e.g., open, closed, partially open), greater than threshold speed and/or acceleration of portal cover movement, and greater than threshold amount of force (e.g., impact) applied to the security device, portal, or port cover.

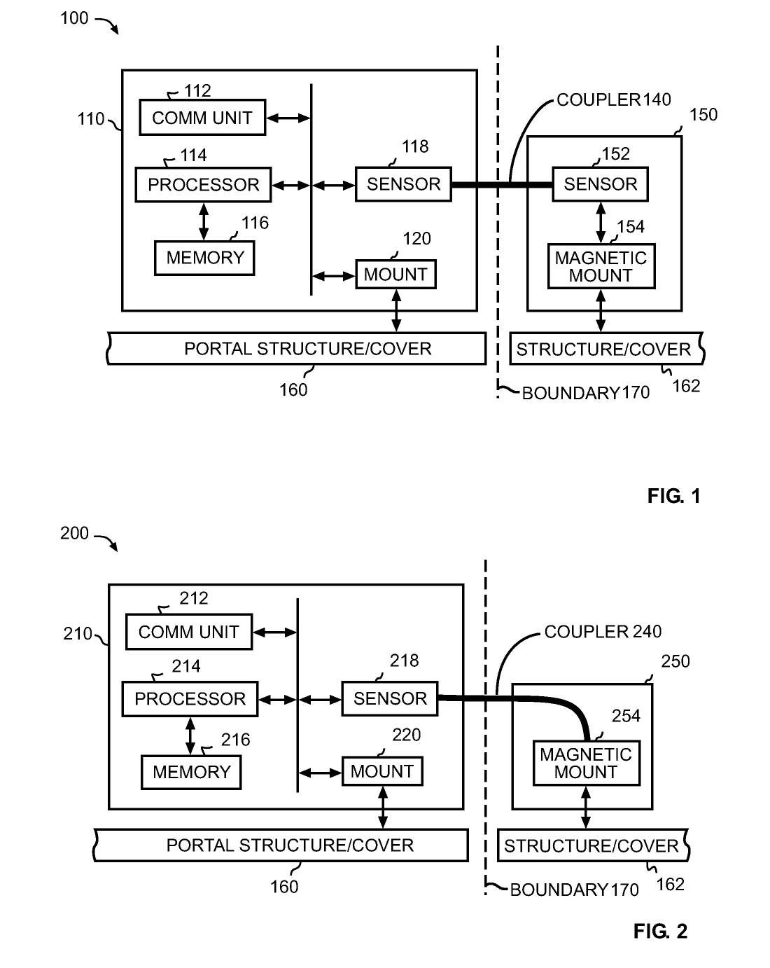

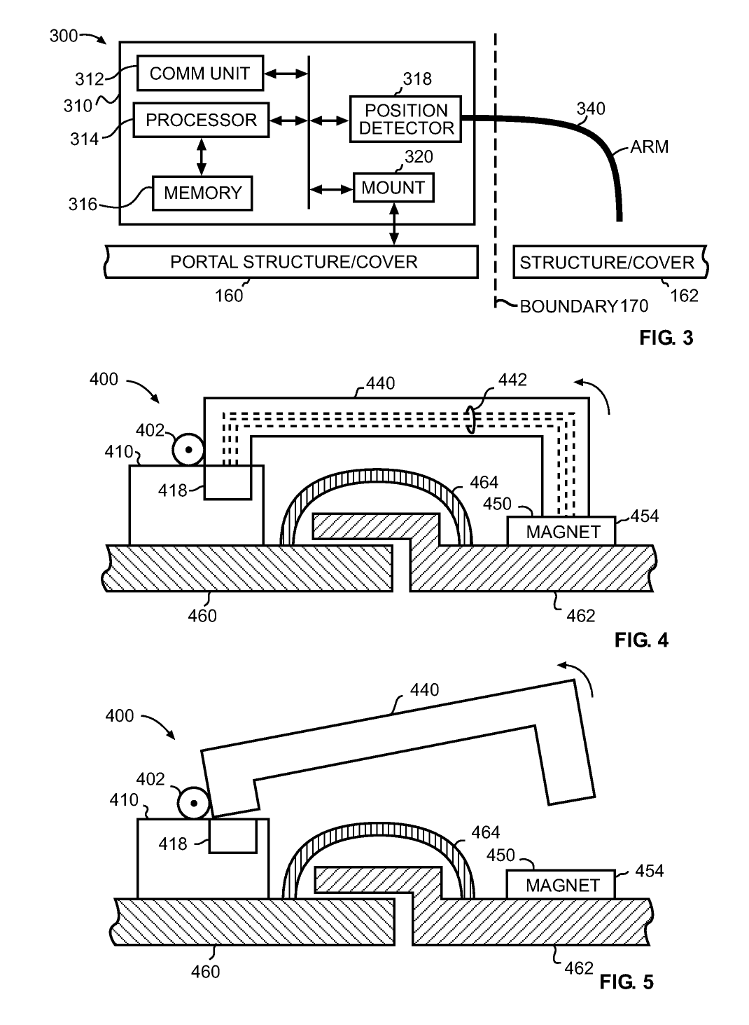

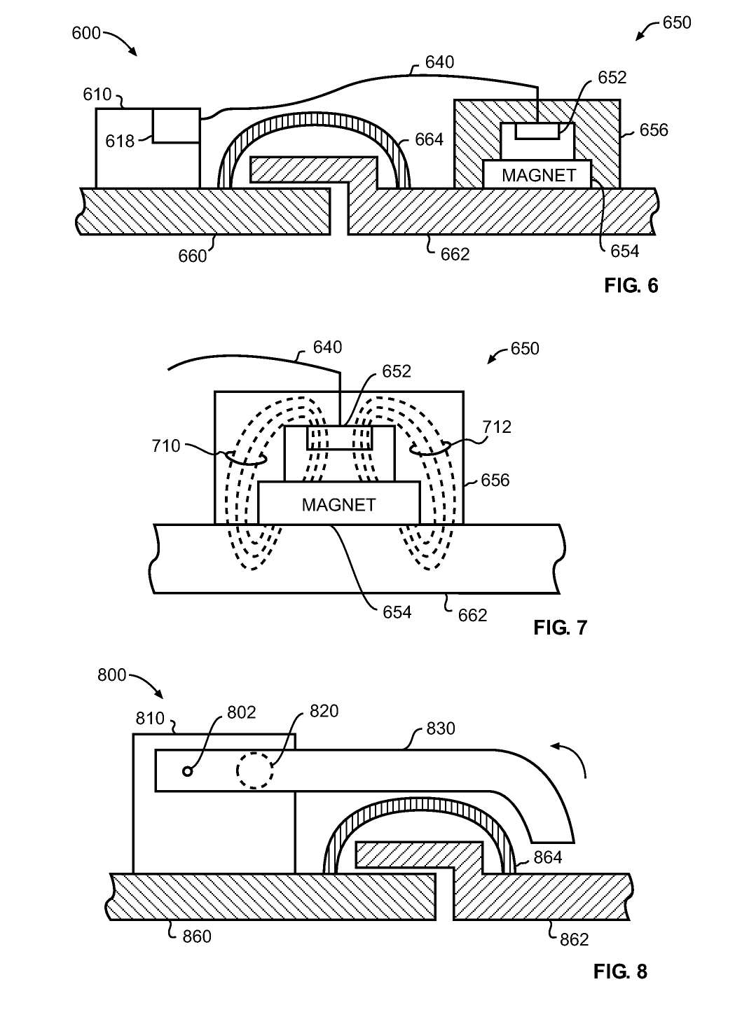

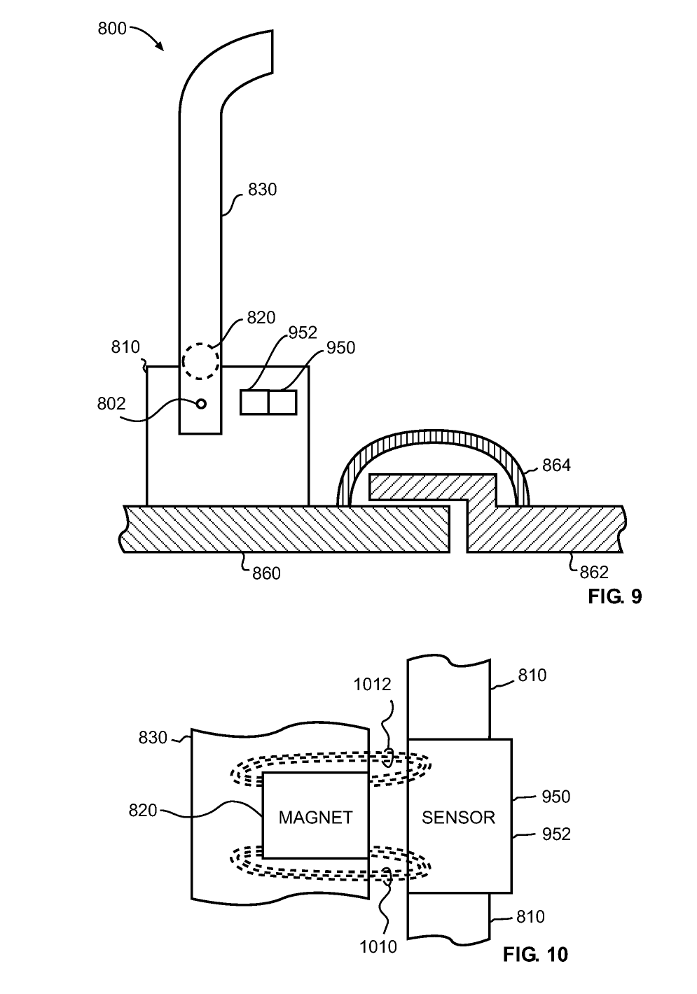

For example, security devices 100, 200, and 300 of FIGS. 1-10, according to various aspects of the present invention, monitor access to an area accessible through a portal by detecting movement of a portal cover, removal of a security device, or removal of a structure that spans across a boundary of a portal or a portal cover.

Security devices 100 and 200 include a main unit, a remote unit, and a coupler between the main unit and the remote unit. The main unit and the remote unit are coupled to a portal structure or a portal cover (e.g., an object) across a boundary between the main unit and the remote unit. At least one of the objects (e.g., portal cover) moves with respect to the other object (e.g., portal cover, portal structure). The coupler couples the main unit to the remote unit across the boundary. Movement of the objects may interfere with the coupler that couples between the main unit and the remote unit. Interference with the coupler may be detected.

For example, security device 100 includes main unit 110, remote unit 150 and coupler 140. Security device 200 includes main unit 210, remote unit 250 and coupler 240. Main unit 110 (210) couples to a portal structure or portal cover (e.g., first object) and the remote unit 150 (250) couples to a portal structure or portal cover (e.g., second object). The first object or the second object moves relative to the other object at boundary 170. Coupler 140 (240) spans from main unit 140 (240) to remote unit 150 (250) across boundary 170.

Security device 300 includes a main unit and an arm. The arm couples to the main unit and spans a boundary of the portal.

For example, security device 300 includes main unit 310 and arm 340. Main unit 310 couples to a portal structure or portal cover (e.g., first object). Arm extends form main unit 310 across boundary 170 and over another portal structure or portal cover (e.g., second object). The first object or the second object moves relative to the other object at boundary 170.

A main unit couples to a portal structure or a portal cover. A main unit may detect removal of the main unit from a portal structure or portal cover. A main unit may receive information (e.g., data) from a user. A main unit may authenticate a user. A main unit may couple to a coupler. A main unit may couple to an arm. A main unit may communicate with a remote unit. A main unit may communicate with a remote unit via a coupler. A main unit may detect movement of an arm.

A main unit provides a notice in accordance with communication with the remote unit or movement of an arm. A communication with a remote unit or detecting movement of an arm may include detecting a physical stimulus, a physical quantity, a physical characteristic, or a change in a physical stimulus, quantity or characteristic. A notice may include information about access, status of a remote unit, status of a main unit, status of a remote unit, a user identity, authentication of a user, operational status, and status of a coupler.

A main unit may include a user interface (e.g., keypad, fingerprint scanner, iris scanner) to receive information from a user. A main unit may include a display for presenting information to a user.

A boundary includes an area at an extent of an object, an area at a limit of an object, and an interface between two objects. A boundary may include the area between the portal covers of a double portal, the area between a portal cover and portal structure, and an area between any portion of a portal structure and any portion of a portal cover. An object may move relative to another object at a boundary. Two objects may move relative to each other at a boundary. One object may overlap another object at a boundary. Movement may increase or decrease an overlap of one object over another. Movement may move one or both objects away from each other or towards each other.

For example, boundary 140 indicates a boundary between portal structure or portal cover 160 and portal structure or portal cover 162. Movement of portal structure or cover 160 may occur relative to portal structure or portal cover 162 at boundary 170. In one implementation, two doors of a double door move past each other at the boundary between the two doors. A door moves relative to a doorframe at a boundary between the door and the doorframe.

A remote unit couples to a portal structure or a portal cover across a boundary from a main unit. A remote unit couples to a coupler. A remote unit may communicate with a main unit via a coupler. A remote unit may provide a physical stimulus or a change in a physical stimulus. A physical stimulus provided by a remote unit may be communicated (e.g., transmitted, sent) to a main unit via a coupler. A remote unit may provide indicia of a physical stimulus or a change in a physical stimulus. A remote unit may communicate indicia to a main unit. A remote unit may communicate indicia via a coupler.

A coupler couples a main unit to a remote unit. A coupler may couple across a boundary. A coupler may provide a medium of communication between a main unit and a remote unit. A communication may include a physical stimulus or a change in a physical stimulus provided by a remote unit and detected by a main unit via the coupler and visa versa. A communication may include information. A coupler includes any conventional material suitable for communicating a physical stimulus, a change in a physical stimulus, or information. For example, an electrical conductor may communicate an electrical stimulus (e.g., signal). A magnetic material may communicate a magnetic field.

Movement at a boundary may decouple a coupler from a main unit or a remote unit. Movement at a boundary may occur upon an operation (e.g., opening, closing, moving, jarring) of a portal cover. A coupler may be decoupled from a main unit or a remote unit upon removal of a main unit or a remote unit from a portal cover or a portal structure. Decoupling a coupler interrupts communication via the coupler. A reverse operation of a portal cover may restore a coupling between a main unit and a remote unit. Restoration of a coupling via a coupler may require human intervention. Decoupling may include severing (e.g., cutting, tearing) the coupler.

An arm couples to a main unit. A main unit detects movement or the position of an arm. An arm moves between a secured position and an unsecured position. In a secured position, an arm extends from a main unit coupled to one object across a boundary to another object. Movement of the objects relative to each other may move the arm from a secured position to an unsecured position. In an unsecured position, the arm does not extend across the boundary to the other object.

Main unit 110 includes communication unit (e.g., comm unit) 112, processor 114, memory 116, sensor 118, and mount 120.

Main unit 210 includes communication unit 212, processor 214, memory 216, sensor 218, and mount 220.

Main unit 310 includes communication unit 312, processor 314, memory 316, position detector 318, and mount 320.

Remote unit 150 includes sensor 152 and magnetic mount 154.

Remote unit 250 includes magnetic mount 254.

Communication units 112, 212, and 312 may perform similar operations and provide similar results. Processors 114, 214, and 314 may perform similar operations and provide similar results. Memory 116, 216, and 316 may perform similar operations and provide similar results. Sensor 118 and 218 may perform similar operations and provide similar results. Mount 120, 220, and 320 may perform similar operations and provide similar results.

A communication unit communicates (e.g., transmits, receives) information. A communication unit may communicate using any conventional medium of communication (e.g., wired, wireless, optical) or protocol (e.g., IEEE 802.11a/b/g/n, IEEE 802.15.4 (Zigbee), Bluetooth, USB, RS232, TCP/IP). A communication unit may communicate information received by a sensor, information calculated by a processor, a notice, an operational log, an error log, an access report, program code, statistical information, and user information. A communication unit may communicate with a processor (e.g., via a bus).

A processor may track time of day and date. A processor may receive a communication from a sensor. A processor may provide a notice in accordance with a communication from a sensor. A processor may receive information from a user. A processor may receive information for verification of a user. A processor may verify a user. A processor may control or coordinate the performance of a function performed by one or more components. A processor may gather information for a log. A processor may provide information for a log to a memory for storage. A processor may track or calculate statistical information about the operation of a system. A processor may communicate statistical information via a communication unit. A processor may provide a report about access. A report may include date and time of access whether authorized or unauthorized, identity of authorized users, removal of a main unit, removal of a remote unit, date and time of removal, coupling of a coupler, decoupling of a coupler, and date and time of coupling or decoupling of a coupler.

A processor includes any conventional microprocessor, signal processor, programmable array, or support circuits. A processor may perform the operations of a sensor or a communication unit. A processor may include circuits for converting a physical stimulus from one form to another (e.g., magnetic to electrical).

A memory receives information, stores information, and provides retrieved information. A memory may organize information. A memory may receive information organized for storage. A memory may store information organized as a log. A log may include one or more entries. A memory may store and provide instructions for execution by a processor. A memory may store variables and temporary data used by a processor. A memory may store communication protocols, variables, or other information used to communicate using a communication unit. A memory may store information about the operation of the system. A memory may store and retrieve a communication from a detector.

An entry of a log may include a date, a time of day, a status of present control signals and a communication from a sensor.

A memory may include any conventional memory (e.g., ROM, RAM, SRAM, EPROM, Flash, hard disk). A processor may include an integrated memory.

A mount couples. A mount may couple a main unit to a portal structure or portal cover. A mount may include any conventional coupling or mounting structure. A mount may include a bolt or a screw. A mount may use a magnetic force to mount. A mount may magnetically mount a main unit to a portal structure or portal cover. A mount may include a magnetic mount of the type disclosed in aforementioned U.S. patent application Ser. No. 11/955,665. A mount may include a quick-release structure to permit coupling or decoupling a main unit to a portal structure or a portal cover without use of tools. A mount may detect removal of the main unit from a portal structure or a portal cover. A mount may provide status (e.g., coupled, decoupled) to a processor. A processor may provide a notice in accordance with a status of a mount.

For example, mount 120 (220, 320) mounts main unit 110 (210, 310) to portal structure or portal cover 160.

A position detector detects a position of an arm. A position detector may detect movement of an arm. A position detector may detect a physical stimulus or a change in a physical stimulus provided by an arm. A position detector may include a magnet and at least one sensor that detects a magnetic field. A change in the magnetic field provided by the magnet may indicate movement of the arm. A position detector may provide a notice to a processor in accordance with detecting.

A magnetic mount mounts to a portal structure or a portal cover. A magnetic mount may provide a magnetic field. A magnetic mount may mechanically mount to a portal structure or portal cover. A magnetic mount may magnetically mount to a portal structure or portal cover formed of a material susceptible to magnetic attraction (e.g., ferrous metal). A material susceptible to magnetic attraction may be mechanically coupled to a portal structure or a portal cover formed of a non-magnetic material to facilitate coupling of a magnetic mount to the portal structure or the portal cover. A magnetic mount may magnetically mount a remote unit to a portal structure or a portal cover. A magnetic mount may include a magnet. A coupler may magnetically couple to a magnetic mount. A magnetic mount may provide a magnetic field to a coupler. A magnetic mount may include structure for positioning a coupler proximate to or touching a magnetic mount.

For example, magnetic mount 154 (254) magnetically mounts to portal structure or portal cover 162. Magnetic mount 254 provides a magnetic field to coupler 240.

A sensor may detect a physical stimulus, a physical quantity, a physical characteristic, and/or a change in a physical quantity or characteristic. A physical stimulus may include a magnetic flux of a magnetic field. A sensor may detect information. A sensor may detect information communicated via a physical stimulus or a change in a physical stimulus. For example, a sensor my detect information from a magnetic field, an electrical signal, or a change in a magnetic field or electrical signal.

A sensor may detect an event and report an event. An event may include a threshold change in a physical stimulus, a presence of a physical stimulus or physical characteristic, and an absence of a physical stimulus or physical characteristic.

A sensor may detect one type of physical stimulus and provide a report via another type of physical stimulus. For example, a sensor may detect a magnetic field and report an event via an electrical signal.

For example, implementation 400 of system 200 includes main unit 410, coupler 440, and remote unit 450. Main unit 410 couples to left portal 460. Remote unit 450 couples to right portal cover 462. Remote unit 450 includes magnet mount 454, which includes a magnet 454. Magnet 454 may magnetically or mechanically couple to right portal 462. Coupler 440 pivotally couples to main unit 410 with pivot 402.

While coupler 440 is positioned such that coupler 440 magnetically couples to magnet 454, coupler 440 communicates magnetic field 442 from magnet 454 to sensor 418 of main unit 410, thus sensor 418 detects magnetic field 442 from magnet 454. While coupler 440 is positioned such that coupler 440 does not magnetically couple to magnet 454, coupler 440 does not communicate a magnet field from magnet 454 to sensor 418. Sensor 418 detects magnetic field 442, a change in magnetic field 442 (e.g., magnitude), or an absence of magnetic field 442.

In this implementation, while sensor 418 detects magnetic field 442, main unit 410 operates consistent with detecting that portal covers 460 and 462 are closed. While portal covers 460 and 462 are closed, main unit 410 does not report a breach of security related to portal covers 460 and 462. While detector 418 does not detect magnetic field 442 or detects a change in the magnitude of magnetic field 442, main unit 410 operates consistent with detecting that portal covers 460 and 462 are open. Upon detecting that portal covers 460 or 462 are open, main unit 410 may provide a notice that indicates a breach of security. Main unit 410 may further receive information from a user and verify that the user is an authorized user thereby precluding a notice of a security breach upon detecting that portal covers 460 or 462 are open.

Movement of either portal 460 or 462 may move coupler 440 away from magnet 454 and disrupt communication of magnetic field 442 to sensor 418. Portal covers 460 and 463 may include weather seal 464 to seal a boundary between portal cover 460 and 462 against the elements. The area between portal cover 460 and portal cover 462 is the boundary between the portal covers. Movement at the boundary occurs when portal cover 460 or 462 moves. Weather seal 464, portal cover 460, or portal cover 462 may contact coupler 440 to move coupler 440 away form magnet 454.

Coupler 440 may further mechanically coupled to remote unit 450 or magnet 454. Coupler 440 may use any conventional mechanical coupling to mechanically couple to magnet 454. Movement of portal cover 460 or 462 may defeat a mechanical coupling to permit coupler 440 to move away from magnet 454. A mechanical coupling between coupler 440 and magnet 454 may increase an amount of movement or a strength of a force required to magnetically decoupled coupler 440 from magnet 454.

In one implementation, coupler 440 is positioned to magnetically couple to magnet 454. Sensor 418 detects magnetic field 442 provided by magnet 454 via coupler 440. Movement of coupler 440 away from magnet 454 disrupts magnetic field 442 in coupler 440. Upon sensing a disruption of magnetic field 442, main unit 410 provides a notice via a communication unit of a security breach.

In an implementation, an authorized user provides identity information to main unit 410. Main unit authenticates the authorized user. The authorized user moves coupler 440 such that magnetic field 442 is disrupted and sensor 418 detects the disruption. Because main unit 410 authenticated the user, main unit 410 does not provide a notice of a security breach.

Main unit 410 may include an electric or magnetic field generator that applies an electric or magnetic field to coupler 440 to demagnetize coupler 440 from residual magnetism that may accumulate in coupler 440.

In another example, implementation 600 of system 100 includes main unit 610, coupler 640, and remote unit 650. Main unit 610 couples to left portal cover 660. Remote unit 650 couples to right portal cover 662. Weather seal 664 seals the boundary between portal cover 660 and 662 against the elements. Remote unit 650 includes magnet mount 654, which mechanically or magnetically couples to portal cover 662, cup 656, which magnetically or mechanically couples to magnetic mount 654, and sensor 652. Coupler 440 electrically couples to main unit 610 across the boundary between portal cover 660 and portal cover 662.

Sensor 652 couples to cup 656. Cup 656 removeably couples to magnetic mount 654. Cup 656 may be removed from magnetic mount 654 and coupled again to magnetic mount 654. While cup 656 is coupled to magnetic mount 654, sensor 652 detects magnetic field 710 and 712. Upon or while detecting magnetic field 710 and 712, sensor 652 sends an electrical signal to sensor 618 of main unit 610. Sensor 618 detects the electrical signal. Main unit 610 construes receipt of the signal as a situation in which portal cover 660 and portal cover 662 are secured.

Removal of cup 656 from magnetic mount 654 moves sensor 652 out of magnetic field 710 and 712. Sensor 652 detects a disruption of magnetic field 710 and 712. Upon detecting or while detecting a disruption, sensor 652 provides an electrical signal to sensor 618 indicating the disruption. Main unit 610 construes receipt of the electrical signal indicating disruption of magnetic fields 710 and 712 as a situation in which portal covers 660 and 662 are not secured. Main unit 610 may provide a notice via a communication unit in accordance with the signal received via coupler 640.

An electrical signal provided by sensor 652 may be continuous, periodic, or provided as needed. The electrical signal may be any conventional electrical signal (e.g., voltage, current, pulse, wave, discrete levels, analog). The electrical signal provided while sensor 652 detects magnetic field 710 and 712 may be different from the electrical signal provided while sensor 652 does not detect magnetic field 710 and 712. Absence of an electrical signal may indicate that sensor 652 does not detect magnetic field 710 and 712. An electrical signal may be a conventionally encoded digital signal or an analog signal. The electrical signal from sensor 652 may be encrypted to provide additional security. Sensor 652 may encrypt the signal prior to providing it to coupler 640.

Sensor 652 may receive electrical power from main unit 610 via coupler 640 for detecting or providing a signal in accordance with detecting.

Decoupling of coupler 640 prevents sensor 652 from providing an electrical signal to sensor 618. In an implementation where the absence of an electrical signal from sensor 652 indicates a security breach, removal of coupler 640 from main unit 610 or remote unit 650 results in detection and notice of a security breach. Movement of portal cover 660 or 662 at the boundary may decoupled coupler 640. An authorized user may decouple coupler 640 or remove remote unit 650 from magnet 654 without triggering a notice of a security breach.

Coupler 640 includes any conventional material (e.g., wire) that conducts electricity. Coupler 640 may include any conventional coupling (e.g., male plug and female socket, hermaphroditic connectors, RJ45, 8P8C, D, USB, BNC, RCA. TRS, DB25, DIN, mini-DIN, XLR, jacks, mini-jacks) to couple coupler 640 to sensor 618 or sensor 652. A conventional electrical coupler may include a seal to seal out contaminants when coupled.

In another example, implementation 800 of system 300 includes main unit 810 and arm 830. Main unit 810 couples to left portal cover 860. Arm 830 pivotally couples to main unit 810 at pivot 802. Arm 830 pivots between a secured position and an unsecured position. In the secured position, arm 830 is positioned across a boundary between left portal cover 860 and right portal cover 862. Weather seal 864 seals the boundary between portal cover 660 and 662 against the elements. In the unsecured position, arm 830 is positioned (e.g., rotated) away from the boundary between portal cover 660 and 662. Movement of portal cover 860 or portal cover 862 may move arm 830 from the secured position to the unsecured position.

Main unit 810 detects movement or the position of arm 830 and provides a notice in accordance with movement of arm 830 and the position of arm 830. Main unit 810 may use any conventional detector (e.g., potentiometer, infrared, capacitive, photoelectric, magnetic field, electrical switch, pressure) to detect motion or position of arm 830.

In an implementation, arm 830 includes magnet 820 and main unit includes at least one sensor 950 and 952 that detects a magnetic field (e.g., Hall effect sensor, a magnetometer, a gaussmeter). While arm 830 is in the secured position, arm 830 is positioned across the boundary between portals 860 and 862 and magnet 820 is position across from (e.g., adjacent, proximate) sensors 950 and 952. Sensor 950 or 952 detects magnetic field 1010 and 1012 from magnet 820. While sensor 950 or 952 detects magnetic field 1010 and 1012, main unit construes arm 830 as being in the secured positioned.

When arm 830 moves out of the secured position, magnet 820 is no longer positioned across from sensor 950 or 952, thus sensor 950 or 952 cannot detect magnetic field 1010 or 1012. The main unit construes the absence of magnetic field 1010 and 1012 as arm 830 being in the unsecured position. The unsecured position includes arm 830 position substantially or entirely on the same side of the boundary as main unit 810.

Movement of portal cover 860 or 862 at the boundary between portal cover 860 and 862 may move arm 830 from the secured position to the unsecured position. Movement of arm 830 may be biased. Arm 830 may be biased at pivot 802 such than arm 830 resists a threshold amount of force while in the secured position, but once the threshold force is applied, arm 830 is biased to pivot to the unsecured position. Arm 830 further remains in the unsecured position until a threshold force is applied to move arm 830 to the secured position. A spring may provide a bias force.

Main unit 810 may provide a notice via a communication unit upon detecting movement from the secured position to the unsecured position or in accordance with the orientation of arm 830.

The foregoing description discusses preferred embodiments of the present invention, which may be changed or modified without departing from the scope of the present invention as defined in the claims. The examples listed in parentheses may be alternative or combined in any manner. The invention includes any practical combination of the structures and method steps disclosed. The words “and” and “or” as used herein shall be construed both conjunctively and disjunctively and each shall include the other (e.g., and/or) whenever practical unless expressly stated otherwise. While for the sake of clarity of description several specifics embodiments of the invention have been described, the scope of the invention is intended to be measured by the claims as set forth below.

What is claimed is:

1. A system for detecting movement of a portal cover, the system comprising:
a main unit having a sensor for detecting a magnetic field;
a remote unit having a magnet that provides the magnetic field; and
a coupler for communicating the magnetic field to the sensor; wherein:
the main unit is coupled to a first object that includes at least one of a portal structure and a portal cover;
the remote unit is coupled to a second object that includes at least one of a portal structure and a portal cover;
at least one of the first object and the second object moves with respect to the other object at a boundary between the first object and the second object;
while the coupler magnetically couples to the main unit and the remote unit across the boundary, the sensor detects the magnetic field via the coupler; and
a movement greater than a threshold of at least one of the first object and the second object magnetically decouples the coupler from at least one of the main unit and the remote unit whereby the sensor does not detect the magnetic field.

2. The system of claim 1 wherein the main unit provides a notice in accordance with the sensor detecting.

3. The system of claim 1 wherein the coupler comprises a ferrous metal.

4. The system of claim 1 wherein the coupler pivotally couples to the main unit.

5. The system of claim 1 wherein the coupler mechanically couples to the remote unit.

6. The system of claim 1 wherein the movement greater than a threshold pivots the coupler away from the remote unit.

7. The system of claim 1 wherein:
the first object comprises a first portal cover;
the second object comprises a second portal cover; and
the first object is position adjacent to the second object.

8. A system for detecting movement of a portal cover, the system comprising:
a main unit;
a remote unit having a magnet that provides a magnetic field and a sensor for detecting the magnetic field; and
a coupler for electrically coupling the main unit to the remote unit; wherein:
the main unit is coupled to a first object that includes at least one of a portal structure and a portal cover;
the magnet is coupled to a second object that includes at least one of a portal structure and a portal cover;
at least one of the first object and the second object moves with respect to the other object at a boundary between the first object and the second object;
while the sensor is positioned proximate to the magnet, the sensor detects the magnetic field and provides an electrical signal in accordance with detecting;
while the coupler electrically couples the main unit to the remote unit across the boundary, the main unit receives the electrical signal via the coupler; and
a movement greater than a threshold of at least one of the first object and the second object decouples the coupler from at least one of the main unit and the remote unit whereby the main unit does not receive the electrical signal.

9. The system of claim 8 wherein while the main unit provides a notice in accordance with the receiving the electrical signal.

10. The system of claim 8 wherein the coupler comprises an electrical conductor.

11. The system of claim 8 wherein while the sensor is not positioned proximate to the magnet, the sensor does not detect the magnetic field and provides an electrical signal in accordance with not detecting.

12. The system of claim 11 wherein the main unit provides a notice in accordance with not detecting.

13. The system of claim 8 further comprising a cup, wherein:
the sensor couples to the cup; and
while the cup is positioned proximate to the magnet, the sensor detects the magnetic field.

14. The system of claim 8 further comprising a cup, wherein:
the sensor couples to the cup;
the cup magnetically couples to the magnet; and
while the cup is magnetically coupled to the magnet, the sensor is positioned proximate to the magnet.

15. A system for detecting movement of a portal cover, the system comprising:
a main unit having a sensor for detecting a magnetic field; and
an arm having a magnet, the arm pivotally coupled to the main unit for movement between a secured position and an unsecured position; wherein:
the main unit is coupled to a first object that includes at least one of a portal structure and a portal cover;
while in the secured position, the arm:
extends from the first object across a boundary to a second object that includes at least one of a portal structure and a portal cover; and
positions the magnet proximate to the sensor whereby the sensor detects the magnetic field;
while in the unsecured position, the arm:
does not extend across the boundary to a second object; and
the magnet is positioned away from the sensor whereby the sensor detects a reduced magnitude of the magnetic field;
at least one of the first object and the second object moves at the boundary with respect to the other object; and
a movement greater than a threshold of at least one of the first object and the second object moves the arm from the secure position to an unsecured position.
